(19) United States
(12) Patent Application Publication
(10) Pub. No.: US 2006/0165975 A1
(43) Pub. Date: Jul. 27, 2006

(54) Substrate comprising a polar plasma-polymerised coating

(76) Inventors: Eva Maria Moser, Lohningen (CH); Heidi Hopp, Besenburen (CH)

Correspondence Address: BACHMAN & LAPOINTE, P.C., 900 CHAPEL STREET, SUITE 1201, NEW HAVEN, CT, 06510, US

(21) Appl. No.: 10/538,229

(22) PCT Filed: Dec. 17, 2003
(86) PCT No.: PCT/CH03/00822

§ 371 Date: Sep. 12, 2005

(30) Foreign Application Priority Data
Dec. 17, 2002 (CH) 2151/02

(51) Int. Cl. B32B 27/00; C23C 16/00

(52) U.S. Cl. 428/336; 428/411.1; 427/248.1

(57) ABSTRACT

Substrates which are coated with a polar plasma-polymerized coating of a thickness (d) in the nanometer range, the coating having multi-functional properties with long-term stability. The process gas contains at least one hydrocarbon that can be substituted and at least one inorganic gas. In a first zone or stage, the substrate is coated using process gases that contain at least one hydrocarbon compound, at least one hydrocarbon compound comprising functional groups containing nitrogen or nitrogen and oxygen and/or at least one inorganic gas containing nitrogen or nitrogen and oxygen. A second zone or stage uses process gases that are devoid of nitrogen and comprise at least one hydrocarbon compound, at least one hydrocarbon compound with functional groups that contain oxygen and/or at least one inorganic gas containing oxygen. The two stages permit a corresponding lower and upper coating to be applied to the substrate.

### BACKGROUND OF THE INVENTION

The invention relates to a method for coating substrates with a polar plasma-polymerised layer with a thickness in the nanometer range, having multifunctional properties with long term stability, wherein the process gas contains at least one each of a hydrocarbon compound, which may be substituted, and at least one inorganic gas. The invention also relates to a coated substrate which is produced according to this method and its use.

It has been known for some time to cover substrates of all types with a thin plasma-polymerised layer. It has been possible to improve the originally poor adhesion of paints, varnishes etc. on the substrate and/or the poor wettability of the substrate with the introduction of low-pressure plasma methods, in particular also with respect to the long term values. The coating of substrates, in particular also of flexible polymer substrates takes place inter alia with a view to the surface composition. It is often also necessary to protect the substrate chemically, physically and/or mechanically. If the plasma-polymerised layer has to simultaneously take on a plurality of functions, this is called a multi-functional layer.

An organic substrate and a method with a coating are known from U.S. Pat. No. 4,465,738 A, which consists of a lower layer made of a plasma-polymerised alkane, for example methane, and an upper layer made of a plasma-polymerised polar organic component. The coating is distinguished by improved wettability and hydrophilicity.

WO 99/39842 A1 brought about a breakthrough. Water-free process gases are used to produce a polar coating by means of plasma polymerisation, whereby a previously not attained long term stability can be attained in this use with at least one each of a hydrocarbon compound, which may be substituted, with up to 8 carbon atoms and an organic gas. The plasma coating has an initial surface tension of at least 45 mN/m, which remains unchanged for at least one year. The layer thicknesses are generally below 100 nm, and are therefore in the nanometer range. To carry out the method, according to pages 5 and 6 of WO 99/39842 A1, bridging paragraph, all low-pressure plasma methods are suitable, for example at a pressure of 1.6×10⁻² mbar. A series of examples is compiled in Table 1 of WO 99/39842 A1. The use of these polar layers with long term stability is extraordinarily diverse as a result of the bonding, i.e. the improved adhesion in relation to polar substances and materials; the printability, scratch protection, anti-fog action and the weldability should be mentioned, in particular.

It is an object of the present invention to provide a method for coating substrates of the most varied types with a plasma-polymerised layer and creating a product of the type mentioned at the outset which further improves the properties even with a widened substrate base, in particular increase the adhesion on the plasma-polymerised layer and of this layer on the substrate.

### SUMMARY OF THE INVENTION

The object is achieved according to the invention in that coating is carried out (a) in a first zone or stage with process gases which contain at least one hydrocarbon compound, at least one hydrocarbon compound with nitrogen-containing or nitrogen- and oxygen-containing functional groups and/or at least one nitrogen-containing or one nitrogen- and oxygen-containing inorganic gas, and (b) in a second zone or stage with nitrogen-free process gases which contain at least one hydrocarbon compound, at least one hydrocarbon compound with oxygen-containing functional groups and/or at least one oxygen-containing inorganic gas.

### DETAILED DESCRIPTION

Using efficient gas mixtures which can be used independently of the pressure range and of the type of discharge, plasma-polymerised polar protective layers with long term stability are possible with the method according to the invention. A way of combining a plurality of layers for multifunctional properties is disclosed. In the case of more than two layers, it is important to the invention that the layer deposited directly onto the substrate is nitrogen-containing, but the upper layer is nitrogen-free but oxygen-containing.

Polar plasma layers, which contain oxygen- and/or nitrogen-containing functional groups, can be produced at much higher pressures than are usual in low pressure methods; because inter alia a certain proportion of air does not damage the processes, but may even be useful, a pressure range up to 1,000 mbar is possible. Under these preconditions, practically all known plasma coating technologies for planar or three-dimensional workpieces, can be used.

The plasma layer according to the invention can be connected downstream or upstream to a production step virtually as desired, regardless of whether the workpiece has already been sluiced in a vacuum chamber and, for example, a metallization is to take place subsequently or whether a bonding coating taking place at atmospheric pressure prior to printing is involved. The workpiece can also be used directly as an anti-fog functional layer.

The surface of the plasma-coated workpieces may be smoother than the untreated substrate. Gentler surface contours favour the surface wetting and therefore the anti-fog effect which is important here. The nitrogen-containing process gases of the first zone or stage, on the one hand, bring about good anchoring of the plasma layer on the substrate and, on the other hand, depending on the control of the process parameters (output, gas mixture) can smooth and/or structure or modulate the surface to a greater or lesser degree. The etching action of aggressive gases, such as for example laughing gas, ammonia and oxygen is primarily decisive for this effect, in particular when these gases are added with an increased proportion.

XPS (X-ray photoelectron spectroscopy) measurements show, or confirm, the expected enrichment with oxygen and nitrogen and the incorporation of oxygen, in particular as hydroxyl, carbonyl or carboxyl (ester) groups.

The plasma-polymerised layers which are deposited according to the invention are distinguished by their controllable multifunctionality; the plasma layer can be adapted to the respective use by varying parameters. All plasma-polymerised layers which are produced according to the invention have long-term stability in common. A further, generally required property is a permanent high surface tension of the plasma-polymerised polar layers, which are therefore hydrophilic and this also means good bonding with respect to dispersion dyes. Further examples of multifunctionality of the polar layers are the mentioned anti-fog effect, the formation of a scratch protection layer, a barrier layer against additives, gases and liquids, which, on the one hand, migrate from the substrate onto the surface or may be deposited by the environment on the surface, or a flame protection layer.

The plasma-polymerised layers are preferably deposited at a process pressure p between 10⁻³ and 1,000 mbar, in particular between 0.1 and 500 mbar. For the reasons mentioned, the process pressure is significantly higher than in comparable conventional methods, in particular also higher than according to WO 99/39842. The plasma reactor is expediently pumped out in advance to a base pressure which is lower than the process pressure, preferably at least about 10 times lower, then filled with process gas. After a coating process below 1,000 mbar, the plasma reactor is flooded, for example with air, nitrogen or argon until the normal pressure is attained and the reactor can be opened. Flooding with argon is too expensive for most processes and air is generally sufficient for this.

The organic compound in the process gas may be a pure hydrocarbon compound or a hydrocarbon compound with substituted functional groups, in particular oxygen- and/or nitrogen-containing polar functional groups.

The hydrocarbon compounds themselves may be of the most varied nature:

alkanes, for example methane, ethane, propane

alkenes, for example ethylene, propylene

alkynes, for example acetylene

polyenes, i.e. hydrocarbons with a plurality of double bonds,

in each case in aliphatic, alicyclic or aromatic form, without or with branch(es).

Acetylene (C₂H₂, ethyne) is used in particular as the layer-forming process gas, the other process gases control the functional groups and can thus also remove atomic layers from the surface.

The hydrocarbons may, as mentioned, be substituted with halogens, such as chlorine and/or fluorine, or be substituted with functional polar groups. Examples of functional polar groups are hydroxyl, carbonyl, carboxylic acid, carboxyl ester, amine, imine, amide and/or conjugated nitrile groups.

When adding silicon-containing process gases, additional SiOₓ-containing functional groups are generated in the lower and/or upper layer and the oxygen content thereby increased. In the process, C-atoms can partly be replaced by Si-atoms.

Both for substituted and non-substituted hydrocarbon compounds, it is advantageous if the molecules contain up to a maximum of 8 C-atoms.

The inorganic component of the process gases advantageously comprises oxygen, carbon dioxide, carbon monoxide, nitrogen, NOx, ammonia, hydrogen, at least one halogen and/or at least one noble gas, but is preferably water-free.

The process gases for depositing the lower and upper layer basically differ only with respect to the nitrogen and/or oxygen content.

The two-stage coating according to the invention is also indicated in particular for food packagings. It has been shown that nitrogen-containing gases clean the substrate surface with the formation of a CN-bond. This leads in addition to improved anchoring of the functional polar groups, which in turn results in a higher chemical resistance. A nitrogen-free, oxygen-containing upper layer is also deposited on this lower layer, which may also be very thin, for example about 0.3 nm, so the nitrogen-containing layer cannot come into contact with food or other nitrogen-sensitive objects.

Two plasma sources are preferably used for depositing a lower and an upper layer. In the first zone/plasma source, a nitrogen-oxygen-hydrocarbon-containing gas mixture is supplied, for example, and a lower layer deposited on the substrate. With the second zone/plasma source, an upper layer is deposited on the lower layer from a nitrogen-free, oxygen-hydrocarbon-containing process gas mixture. Plasma chambers with two plasma sources, as are used here, are known to the person skilled in the art.

According to a further variant, a single plasma source can be used and the nitrogen-hydrocarbon-containing or nitrogen-oxygen-hydrocarbon-containing gas mixture may be introduced first, and the oxygen-hydrocarbon-containing process gas mixture be introduced during the second pass.

With respect to the product, the object is achieved according to the invention in that a plasma-polymerised polar layer in the nanometer range is applied as a nitrogen-containing lower layer applied to the substrate, and a nitrogen-free, oxygen-containing polar upper layer is applied thereon. Special and developing embodiments of the product emerge from the dependent claims.

The nitrogen-containing lower layer preferably has a proportion of 40 to 90% of the total layer thickness, the polar upper layer has a proportion of 60 to 10% of the total layer thickness, preferably about 50% in each case. The entire layer thickness is preferably in the range of 1 to 100 nm. The coated substrates can be welded to one another.

In a layer, with a lower and upper layer made of hydrocarbon compounds with oxygen-containing functional groups, the oxygen/carbon ratio is preferably in the range of 0.03 to 0.8 in each case, and in the lower layer the nitrogen/carbon ratio is in the same range. The polar upper layer, averaged in the uppermost about 2 nm, i.e. on the surface, preferably has an oxygen/carbon ratio of 0.2 to 0.6, preferably of 0.3 to 0.5 and a permanent surface tension of at least 50 mN/m. Carboxyl groups raising the oxygen content can be formed on the surface of the upper layer. A good anti-fog effect is ensured, in particular, with the high surface tension, in particular with a suitable surface topography.

The layer according to the invention can be deposited on all types of substrates, for example on polymer, glass-like, ceramic, metallic or natural surfaces, in particular on a polycarbonate, polyethylene terephthalate, polypropylene, polyethylene, polyamide, fluoropolymers, wool, cotton, silk, glass, ceramic or else composite materials, all materials including natural, in the form of films, moulded bodies, containers, textiles, non-wovens, membranes, granules, powders, fibres, grids and yarns, containers and also in the form of coated or activated or treated surfaces of materials of all types.

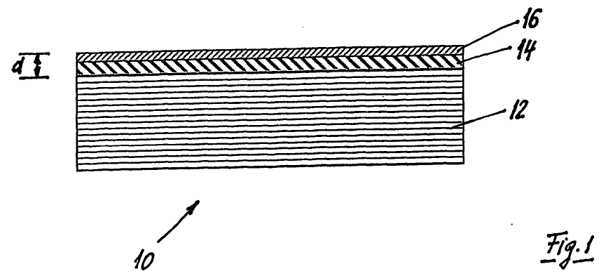

A product according to the invention is described in more detail with the aid of a layer construction shown schematically in FIG. 1. This figure shows a coated substrate 10 with a substrate 12, a lower layer 14 and an upper layer 16. The two polar plasma-polymerised layers 14, 16 in the present case have a total thickness d of about 10 nm. The lower layer 14 is nitrogen-containing, it has excellent adhesion with the substrate 12. A possible amine formation could be disadvantageous because of the lower layer 14. This disadvantage is prevented by the oxygen-containing, but low in nitrogen to nitrogen-free upper layer 16.

### EXAMPLE

### Multilayer Deposit with a Microwave Discharge

A thin lower layer 14 is deposited on a substrate 12 with a microwave source at 2.45 GHz, using a process gas mixture of acetylene, carbon dioxide, laughing gas and argon, which is introduced in the first zone at the plasma source or at the first plasma source. In the second zone or the second plasma source, the gas mixture acetylene, carbon dioxide and argon is introduced to produce the upper layer. At a pressure range of 0.01 to 320 mbar and an output range of 60 to 2,000 watt, surface tensions of 54 to 75 mN/m were attained on the substrates polyester, polypropylene and polyethylene, and have a polar fraction of 23 to 51 mN/m and are characterised by an oxygen to carbon ratio of 0.3 to 0.5 and a carboxyl groups to carbonyl groups ratio of 0.2 to 1.2. The surface tension can inter alia also be controlled by the feed speed. The ratio of oxygen to carbon and the ratio of the carboxyl groups to the carbonyl groups in the uppermost atom layers of the deposited layers was determined with the surface-sensitive XPS (photoelectron spectroscopy).

The same layer properties can be attained with all other discharge types with respective excitation frequencies of zero to 20 GHz and can be attained in each case with or without magnetic field support. Mentioned by way of example are DBDs (dielectric barrier discharges), low pressure to atmospheric pressure glow discharges, APNEDs (atmospheric pressure non-equilibrium discharges), surface discharges, plasma nozzles and plasma wide beam burners.

1-14. (canceled)

15. Method for coating substrates (12) with a polar plasma-polymerised layer with a thickness (d) in the nanometer range, having multifunctional properties with long-term stability, wherein the process gas contains at least one each of a hydrocarbon compound, which may be substituted, and at least one inorganic gas, comprises coating
(a) in a first zone or stage with process gases which contain at least one hydrocarbon compound, at least one hydrocarbon compound with nitrogen-containing or nitrogen- and oxygen-containing functional groups and/or at least one nitrogen-containing or one nitrogen- and oxygen-containing inorganic gas, and
(b) in a second zone or stage with nitrogen-free process gases which contain at least one hydrocarbon compound, at least one hydrocarbon compound with oxygen-containing functional groups and/or at least one oxygen-containing inorganic gas.

16. Method according to claim 15, wherein coating is carried out at a process pressure (p) of 10⁻³≦p≦1,000 mbar.

17. Method according to claim 15, wherein coating is carried out at a process pressure (p) of 0.1≦p≦500 mbar.

18. Method according to claim 15, wherein coating is carried out with process gases, which contain, as organic components, hydrocarbon compounds with up to a maximum of 8 C-atoms, and, as inorganic components, oxygen, nitrogen, hydrogen, carbon dioxide, carbon monoxide, nitrogen oxides, ammonia, at least one halogen and/or at least one noble gas.

19. Method according to claim 15, wherein at least one of a lower and upper layer (14, 16) is deposited with additional silicon-containing process gases.

20. Method according to claim 15, wherein coating is carried out with a process gas which contains aliphatic, alicyclic and/or aromatic hydrocarbon compounds, preferably with functional polar groups, such as hydroxyl-carbonyl-, carboxylic acid-, carboxyl ester-, amine-, imine-, amide- and/or conjugated nitrile groups.

21. Method according to claim 19, wherein the nitrogen-containing or nitrogen- and oxygen-containing lower layer (14) is applied with a first plasma source, the oxygen-containing upper layer (16) is applied with a second plasma source, or the lower layer (14) and the upper layer (16) are applied from the same plasma source with process gases fed in at various zones or alternating process gases.

22. Coated substrate (10) with at least two multifunctional layers (14, 16) deposited by means of plasma polymerisation, and made of hydrocarbon compounds, comprising a plasma-polymerised polar layer (14, 16) in the nanometer range comprises a nitrogen-containing lower layer (14) applied to the substrate (12), and a nitrogen-free, oxygen-containing polar upper layer (16) applied to the substrate.

23. Coated substrate (10) according to claim 22, wherein the nitrogen-containing or nitrogen- and oxygen-containing lower layer (14) has a proportion of 40 to 90% of the total layer thickness (d) and the upper layer (16) has a proportion of 60 to 10% of the total layer thickness (d), wherein the layer thickness is between 1 to 100 nm.

24. Coated substrate (10) according to claim 23, wherein the nitrogen/carbon and/or the oxygen/carbon ratio present in the plasma-polymerised polar layer (14, 16) made of substituted hydrocarbon compounds is in the range of 0.3 to 0.8, and in the lower layer (14), the nitrogen/carbon ratio is in the same range.

25. Coated substrate (10) according to claim 23, wherein the polar upper layer (16) has a carbon/oxygen ratio of 0.2 to 0.6 and a permanent surface tension of preferably at least 50 mN/m.

26. Coated substrate (10) according to claim 22, wherein the substrate is welded to a plasma-polymerised polar layer (14, 16).

27. Coated substrate (10) according to claim 22, wherein the substrate forms a layer (14, 16) for packaging.

28. Coated substrate (10) according to claim 27, wherein the packaging is for food.

29. Coated substrate (10) according to claim 27, wherein the substrate forms a protective layer against gases, additives and liquids.
